(19) United States
(12) Patent Application Publication
(10) Pub. No.: US 2025/0270696 A1
(43) Pub. Date: Aug. 28, 2025

(54) GAS INJECTOR ASSEMBLY WITH IMPROVED GAS MIXING

(71) Applicant: Applied Materials, Inc., Santa Clara, CA (US)

(72) Inventor: Muhannad Mustafa, Milpitas, CA (US)

(73) Assignee: Applied Materials, Inc., Santa Clara, CA (US)

(21) Appl. No.: 18/590,478

(22) Filed: Feb. 28, 2024

(51) Int. Cl. C23C 16/455

(52) U.S. Cl. CPC C23C 16/45548; C23C 16/45565

(57) ABSTRACT

Gas inserts for semiconductor manufacturing processing chambers with a plurality of injection levels are described. Each of the gas injection levels provides a gas flow to an inner channel within the gas insert. Each of the gas flows are directed in a rotational direction within the inner channel. The gas injection level closest to the outlet end of the gas insert directs a gas flow in the opposite rotational direction to the other gas injection levels. Processing chambers, gas distribution assemblies and methods using the gas inserts are also described.

### TECHNICAL FIELD

Embodiments of the disclosure are directed to gas injectors for semiconductor manufacturing processing chambers. In particular, embodiments of the disclosure are directed to gas injectors with improved mixing for semiconductor manufacturing processing chambers.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications.

Current gas injectors use a cap insert that cannot ensure efficient gas mixing at wide range of process pressure for atomic layer deposition (ALD), or co-flow for chemical vapor deposition (CVD) processes. Multiple tangential and gas entry ports are used to create a vortex inside the cap insert during gas delivery. Current designs result in an entry port signature recognizable in the deposited films due to the gas mixing depending on the types of process being used.

Accordingly, there is a need in the art for improved gas mixing for gas injectors of processing chambers.

### SUMMARY

One or more embodiments of the disclosure are directed to gas inserts for semiconductor manufacturing processing chambers. The gas inserts include a plurality of gas injection levels. Each gas injection level provides a gas flow to an inner channel within the gas insert. Each of the gas flows are directed in a rotational direction within the inner channel. The gas injection level closest to an outlet end of the gas insert directs a gas flow in an opposite rotational direction than the other gas injection levels.

Additional embodiments of the disclosure are directed to gas inserts for semiconductor manufacturing processing chambers. The gas inserts include an inlet end having an inlet end wall with a plurality of openings extending therethrough, and an outlet end having an outlet end face. The inlet end and outlet end define a length of the gas insert. An inner channel extends from the inlet end wall to the outlet end with an opening in the outlet end face. The inner channel is bounded by a channel wall. The gas inserts include a plurality of gas injection levels. Each gas injection level includes a peripheral recess in an outer peripheral wall of the gas insert. The plurality of gas injection levels includes an inlet end gas injection level and an outlet end gas injection level. Each of the peripheral recesses have a plurality of angled apertures extending from a bottom surface of the peripheral recess to the inner channel.

Further embodiments of the disclosure are directed to gas injector assemblies for semiconductor manufacturing processing chambers. The assemblies include a showerhead, a backing plate, a gas insert and a gas manifold. The showerhead has a front surface and a back surface with a plurality of apertures extending therethrough. The backing plate has a front surface with a concave portion and a back surface with an opening extending to the concave portion of the front surface. The backing plate is positioned adjacent the back surface of the showerhead to form a plenum between the concave portion of the front surface and the back surface of the showerhead. The gas insert has an outlet end in contact with the back surface of the backing plate. The gas insert includes a plurality of gas injection levels, each gas injection level providing a gas flow to an inner channel within the gas insert. Each of the gas flows are directed in a rotational direction within the inner channel. The gas injection level closest to an outlet end of the gas insert directs a gas flow in an opposite rotational direction than the other gas injection levels. The inner channel is in fluid communication with the plenum through the back surface of the backing plate. The gas manifold is around the gas insert. The gas manifold cooperatively interacts with the gas insert to form peripheral recesses for the gas injection levels.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a processing chamber in accordance with one or more embodiment of the disclosure;

FIG. 2 shows an expanded view of a gas distribution assembly with a gas insert according to one or more embodiment of the disclosure;

FIG. 3 shows a side view of a gas insert according to one or more embodiment of the disclosure, the internal structure of which is shown in dotted lines;

FIG. 4 shows a cross-sectional view of the gas insert of FIG. 3 taken through the center of the inner channel;

FIG. 5 shows a cross-sectional view of the gas insert of FIG. 3 taken along line 5-5′; and

FIG. 6 shows a cross-sectional view of the gas insert of FIG. 3 taken along line 6-6′.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

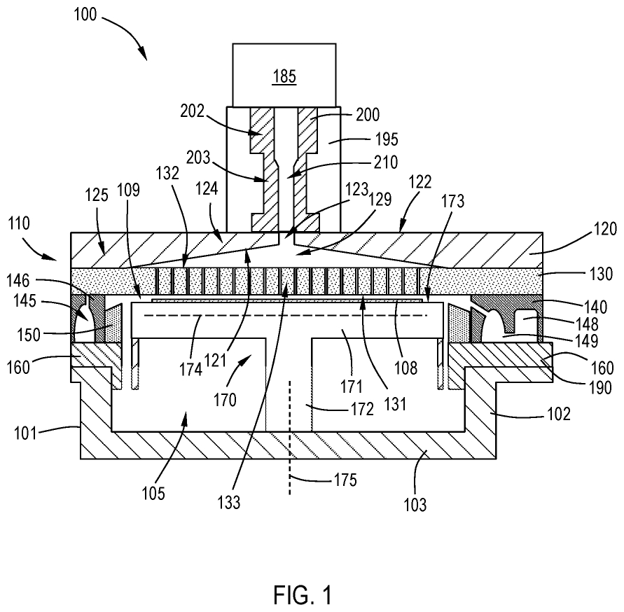

With reference to FIG. 1, one or more embodiments of the disclosure are directed to a semiconductor manufacturing processing chamber 100. The semiconductor manufacturing processing chamber 100 comprises a chamber body 101 having sidewalls 102 and a bottom wall 103 surrounding a chamber interior 105. The sidewall 102 and bottom wall 103 can be integrally formed or separate component connected together by any suitable connection or fastener known to the skilled artisan.

The semiconductor manufacturing processing chambers 100 of some embodiments includes a gas distribution assembly 110. The gas distribution assembly 110 comprises a backing plate 120 and a faceplate 130. In some embodiments, the processing chamber 100 further comprises a pumping ring 140. In some embodiments, the pumping ring 140 is considered a separate part from the gas distribution assembly 110.

Chamber body 101, in conjunction with the gas distribution assembly 110 encloses the chamber interior 105 of the semiconductor manufacturing processing chamber 100. During processing, the chamber interior 105 of the semiconductor manufacturing processing chamber 100 is typically maintained at a controlled pressure (usually a low-pressure environment) using one or more gas inlet (not shown) and one or more exhaust (not shown). The skilled artisan will be familiar with the general construction of the chamber body 101 and the use of gas inlets and exhaust systems.

The backing plate 120 has a front surface 121 and a back surface 122 that define a thickness of the backing plate 120. The backing plate 120 has an inner portion 124 and an outer portion 125. The backing plate 120 contacts the faceplate 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 of some embodiments is concentric with the inlet opening 123. While the backing plate 120 of some embodiments has an oblong or non-symmetrical shape, the central axis remains at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124 at the transition to the outer portion 125, as illustrated in the Figures. In some embodiments, the concave shape has a curved profile from the inlet opening 123 to the outer peripheral edge of the inner portion 124.

The gas distribution assembly 110 includes a faceplate 130, which may also be referred to as a “showerhead”. The faceplate 130 has a front surface 131 and a back surface 132 defining a thickness of the faceplate 130. The faceplate 130 has an inner portion 133 and an outer portion 134. The inner portion 133 of the faceplate 130 aligns with the inner portion 124 of the backing plate 120 and the outer portion 134 of the faceplate 130 aligns with the outer portion 125 of the backing plate 120. The inner portion 133 of the faceplate 130 comprises a plurality of apertures 135 extending through the thickness of the faceplate 130.

The backing plate 120 can be connected to the faceplate 130 by any suitable mechanism known to the skilled artisan. For example, the backing plate 120 can be welded to the faceplate 130. In some embodiments, the backing plate 120 is connected to the faceplate 130 with a plurality of fasteners. Suitable fasteners include, but are not limited to, bolts with or without O-rings.

When the front surface 121 of the outer portion 125 of the backing plate 120 is in contact with the outer portion 134 of the back surface 132 of the faceplate 130, a gas box plenum 129 is formed in the space between the front surface 121 of the inner portion 124 of the backing plate 120 and the inner portion 133 of the back surface 132 of the faceplate 130.

In some embodiments, the gas box plenum 129 has a coating to improve chemical compatibility. In some embodiments, the coating covers the entire front surface 121 of the backing plate 120 and the entire back surface 132 of the faceplate 130, including in the inlet opening 123 of the backing plate 120 and the plurality of apertures 135 of the faceplate 130. In some embodiments, the coating is only on the portions of the backing plate 120 and faceplate 130 that will come into contact with the process gases.

In some embodiments, the gas distribution assembly 110 further comprises a gas manifold 195 connected to the back surface 122 of the backing plate 120. The gas manifold 195 has a gas insert 200 with an inner channel 210 aligned with the opening 123 in the center of the backing plate 120. The inner channel 210 of some embodiments has an upper portion 202 and a lower portion 203. The upper portion 202 has a larger inner diameter than the inner diameter of the lower portion 203.

Conventional gas distribution assemblies either do not incorporate a gas insert or use a gas insert that suffers from insufficient gas mixing. During deposition, the non-uniform gas mixing is revealed as an entry port signature in the deposited film. The gas insert of the present disclosure advantageously provides efficient gas mixing at a wide range of process pressures for ALD processes, and improved co-flow in CVD processes.

Some embodiments of the disclosure improve gas mixing with two or more gas injection levels with tangential entry ports with a first rotation direction (e.g., clockwise or anti-clockwise), and one or more bottom gas injection level with tangential entry ports configured to provide a flow of gas in a second direction opposite the first direction. The inventor has found that the addition of the lower injection level generates significant turbulence and acts as a gas curtain to increase the residence time of the gases mixing from the other injection levels before entering the gas box plenum 129. The bottom injection level can be configured to supply sufficient kinetic energy to break the laminarity of the precursor delivery from the upper injection levels and improve mixing efficiency and uniformity.

Accordingly, some embodiments are directed to gas inserts for semiconductor manufacturing processing chambers. The gas insert comprises a plurality of gas injection levels, each gas injection level providing a gas flow to an inner channel within the gas insert. Each of the gas flows are directed in a rotational direction within the inner channel. The gas injection level closest to the outlet end of the gas insert directs a gas flow in an opposite rotation direction than the other gas injection levels. The rotational direction of the gas flows within the inner channel causes gases to flow around the longitudinal axis of the gas insert which extends from the inlet end to the outlet end of the gas insert.

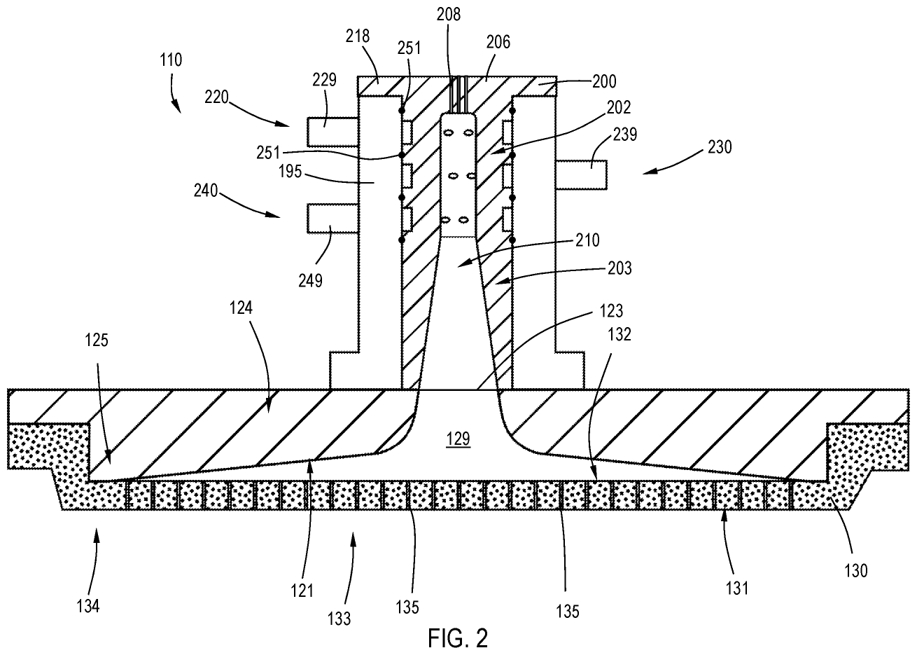

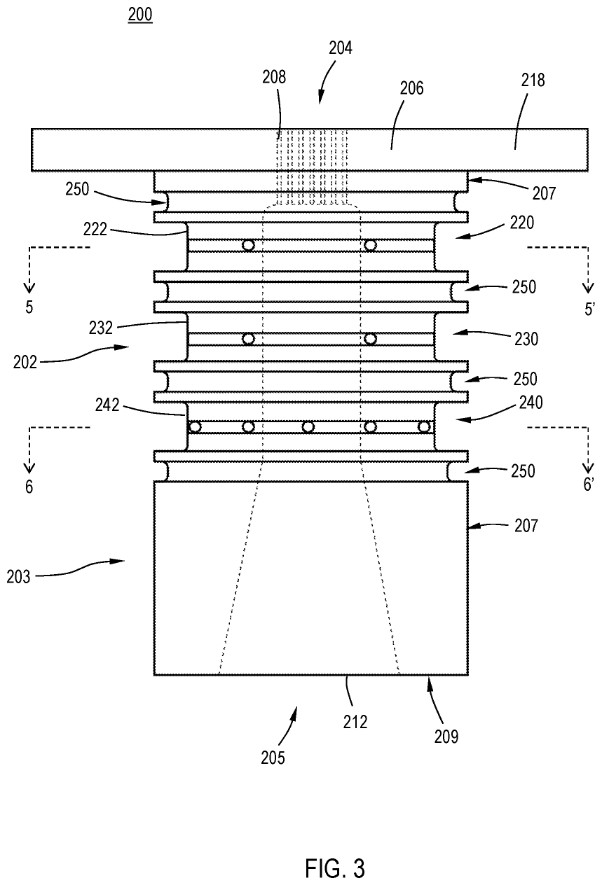

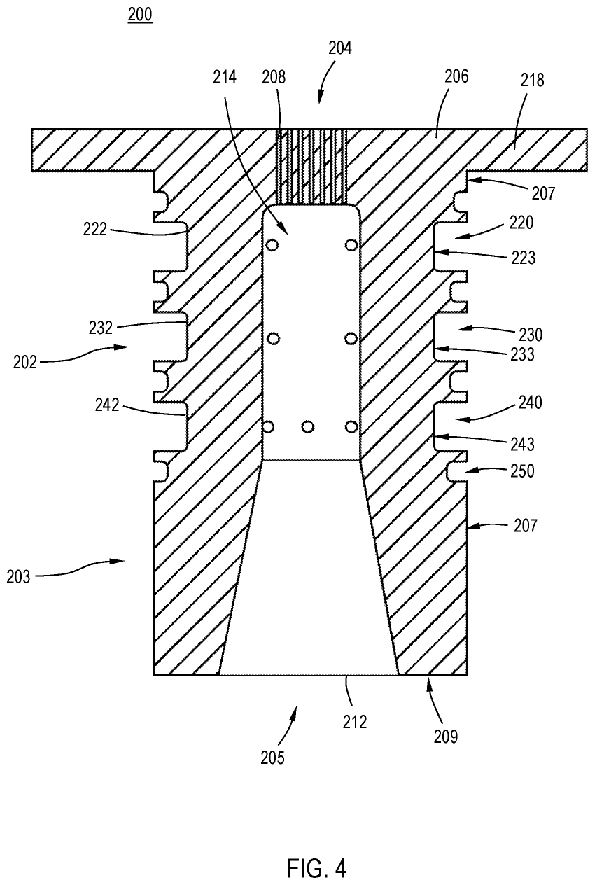

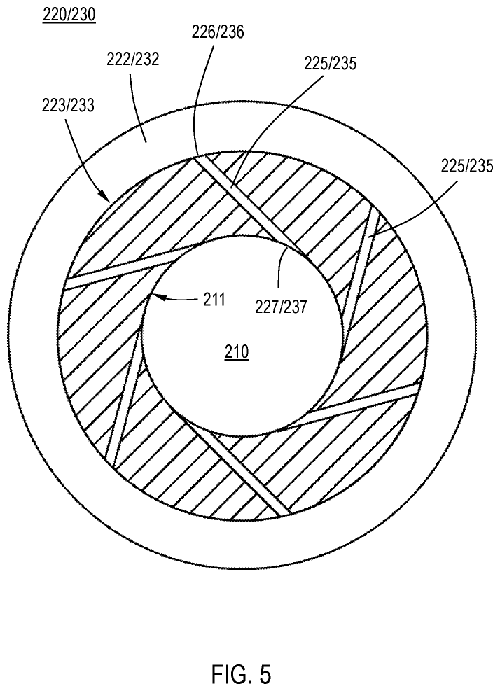

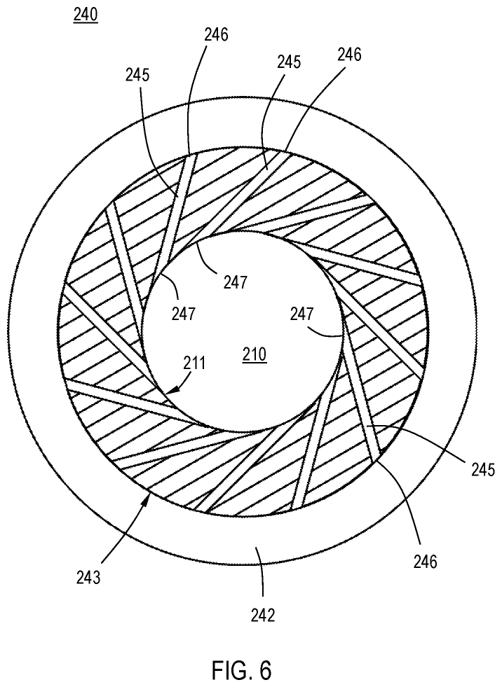

FIG. 2 shows an expanded view of a gas distribution assembly 110 with a gas insert 200 according to one or more embodiment of the disclosure. FIG. 3 shows a side view of a gas insert 200 according to one or more embodiment of the disclosure, the internal structure of which is shown in dotted lines. FIG. 4 shows a cross-sectional view of the gas insert 200 of FIG. 3 taken through the center of the inner channel 210. FIG. 5 shows a cross-sectional view of the gas insert 200 of FIG. 3 taken along line 5-5′. FIG. 6 shows a cross-sectional view of the gas insert 200 of FIG. 3 taken along line 6-6′.

With reference to FIGS. 2 through 6, one or more embodiments of the disclosure are directed to gas inserts 200 for a semiconductor manufacturing processing chamber 100. The gas insert 200 comprises a plurality of gas injection levels 220, 230, 240 providing a gas flow to an inner channel 210 within the gas insert 200. Each of the gas flows are directed in a rotational direction within the inner channel 210, with the gas level closest to the outlet end 205 of the gas insert 200 directs a gas flow in an opposite rotational direction than the other gas injection levels.

The embodiments illustrated in the Figures have three gas injection levels. However, the skilled artisan will recognize that there can be more than three gas injection levels with at least the gas injection level closest to the outlet end 205 of the gas insert 200 directing a gas flow in the opposite rotational direction from at least one of the gas injection levels above. In some embodiments, the gas injection level closest to the outlet end 205 of the gas insert 200 directs a gas flow in a direction opposite the other gas injection levels. In some embodiments, at least two gas injection levels direct gas flows opposite at least two other gas injection levels. For example, in an alternating arrangement, or stacked with the at least two opposite flow injection levels closest to the outlet end 205.

In some embodiments, the plurality of gas injection levels comprises an inlet end gas injection level 220 closest to the inlet end 204 of the gas insert 200 and the gas injection level 240 closest to the outlet end outlet end 205 of the gas insert 200. The inlet end 204 and outlet end 205 defining a length of the gas insert 200.

In the illustrated embodiment, there are three gas injection levels: an inlet end gas injection level 220 closest to the inlet end 204 of the 200, an intermediate gas injection level 230, and an outlet end gas injection level 240. The outlet end gas injection level 240 is closest to the outlet end 205 of the gas insert 200. Stated differently, the outlet end gas injection level 240 is furthest from the inlet end 204 of the gas insert 200.

The gas insert 200 has an outer peripheral surface 207 that, in combination with the gas manifold 195 creates a plurality of injection level recesses. In the illustrated embodiment, a plurality of peripheral recesses is formed in the outer peripheral surface 207 of the gas insert 200 so that when the gas insert 200 is within the gas manifold 195, a plurality of injection level recesses is formed. Stated differently, the gas manifold 195 is around the gas insert 200, and the gas manifold 195 cooperatively interacts with the gas insert 200 to form peripheral recesses of the gas injection levels. The skilled artisan will recognize the complementary nature of the gas insert 200 within the gas manifold 195 and the injection level recesses can be formed on the inner surface of the gas manifold 195 so that the injection levels are formed upon assembly with the gas insert 200.

In the illustrated embodiment, each gas injection level 220, 230, 240 comprises a peripheral recess 222, 232, 242 in the outer peripheral surface 207 of the gas insert 200. Each peripheral recess 222, 232, 242 comprises a plurality of angled apertures 225, 235, 245 extending from a bottom surface 223, 233, 243 of the respective peripheral recess 222, 232, 242 to the inner channel 210. Each of the angled apertures 225, 235, 245 have an outer opening 226, 236, 246 as the bottom surface 223, 233, 243 of the respective peripheral recess 222, 232, 242, and an inner opening 227, 237, 247 at the channel wall 211 of the inner channel 210.

The number of angled apertures 225, 235, 245 in each of the peripheral recesses 222, 232, 242 can affect the gas flow and mixing efficiency within the 210. In some embodiments, the inlet end gas injection level 220 comprises in the range of 4 to 10 angled apertures 225 spaced around the bottom surface 223 of the peripheral recess 222. In some embodiments, the intermediate gas injection level 230 comprises in the range of 4 to 10 angled apertures 235 spaced around the bottom surface 233 of the peripheral recess 232. In some embodiments, there is the same number of angled apertures 225 in the inlet end gas injection level 220 as the number of angled apertures 235 in the intermediate gas injection level 230. In some embodiments, there are a different number of angled apertures 225 in the inlet end gas injection level 220 than angled apertures 235 in the intermediate gas injection level 230.

The angled apertures 225 are illustrated as being evenly spaced around the bottom surface 223 of the inlet end gas injection level 220 and the angled apertures 235 are evenly spaced around the bottom surface 233 of the intermediate gas injection level 230. However, the skilled artisan will recognize that the distribution of angled apertures is not limited to being evenly spaced. The cross-sectional view of FIG. 5 taken along line 5-5′ of FIG. 3 could also be considered the cross-sectional view through the intermediate gas injection level 230 if the number and angles of the angled apertures are the same for the two levels. In some embodiments, the angled apertures 235 of the intermediate gas injection level 230 are vertically aligned with the angled apertures 225 of the inlet end gas injection level 220 so that cross-sectional views through the inlet end gas injection level 220 and intermediate gas injection level 230 would look the same. In some embodiments, the angled apertures of the intermediate gas injection level 230 as rotated around the longitudinal axis of the gas insert 200 (extending through the center of the inner channel 210 from the inlet end 204 to the outlet end 205. In some embodiments, the angled apertures of the intermediate gas injection level 230 are collectively rotated around the longitudinal axis by an amount about one half the spacing of the apertures in the inlet end gas injection level 220. For example, in the illustrated embodiment, there are six angled apertures evenly spaced (every 60°) around the inner channel 210, and the six angled apertures of the intermediate gas injection level 230 are evenly spaced (every 60°) around the inner channel 210 but offset from the angled apertures of the inlet end gas injection level 220 by 30°. The skilled artisan will recognize that this is merely one possible configuration and that other configurations are within the scope of the disclosure. For example, if there are three gas injection levels above the outlet end gas injection level 240, and each of the three gas injection levels have six evenly spaced openings, each of the three gas injection levels could be offset by 20° from each other.

In some embodiments, the outlet end gas injection level 240 comprises in the range of 6 to 24 angled apertures 245 spaced around the bottom surface 243 of the peripheral recess 242. In some embodiments, there are more angled apertures 245 in the outlet end gas injection level 240 than either of the inlet end gas injection level 220 or intermediate gas injection level 230. In some embodiments, the outlet end gas injection level 240 has greater than or equal to 1.5×, 1.75×, 2×, or 2.5× of the number of angled apertures in the inlet end gas injection level 220 and/or the intermediate gas injection level 230. In the embodiment illustrated, the inlet end gas injection level 220 and intermediate gas injection level 230 each have six angled apertures and the outlet end gas injection level 240 has twelve angled apertures, as can be seen from the cross-sectional views of FIGS. 5 and 6.

The angle that the apertures direct gas flows into the inner channel 210 can impact the mixing and vortex efficiencies. In some embodiments, the angled apertures 225, 235, 245 of one or more of the inlet end gas injection level 220, intermediate gas injection level 230 or outlet end gas injection level 240 are angled tangential to channel wall 211 of the inner channel 210. The skilled artisan will be aware of the geometric nature of a tangent line to the circular cross-section of the inner channel 210. As used in this specification and the appended claims, an angled aperture is tangential if a longitudinal axis of the aperture intersects of touches the cross-sectional radius of the inner channel 210 at an angle within ±2°, ±1° or ±0.5° of perpendicular (i.e., 90°). Stated differently, the longitudinal axis of the angled apertures intersects or touches the cross-sectional radius of the inner channel 210 at an angle in the range of 88-92°, or 89-91°, or 89.5-90.5°.

As illustrated, the angled apertures of the injection levels are angled inwardly toward the inner channel 210 while remaining substantially perpendicular to the longitudinal axis of the inner channel 210. In some embodiments, at least one of the angled apertures is further angled toward the outlet end 205 and gas insert 200. In some embodiments, the plurality of angled apertures 225, 235, 245 in one or more of the inlet end gas injection level 220, intermediate gas injection level 230 or outlet end gas injection level 240 are angled toward the outlet end 205 of the gas insert 200 and connect to the inner channel 210 tangential to the channel wall 211.

In some embodiments, the angled apertures of the various injection levels have a diameter in the range of 0.25 mm to 5 mm, or in the range of 0.5 mm to 4.5 mm, or in the range of 0.75 mm to 4 mm, or in the range of 1 mm to 3.5 mm, or in the range of 1.5 mm to 3.25 mm, or in the range of 2 mm to 3 mm. In some embodiments, the angled apertures 245 of the outlet end gas injection level 240 have a smaller diameter than the angled apertures 225 of the inlet end gas injection level 220 or the angled apertures 235 of the intermediate gas injection level 230.

The gas insert 200 has an inlet end 204 with an inlet end wall 206 with an inlet end face and an inlet end inner channel face within the inner channel 210, and an outlet end 205 with an outlet end face 209. In some embodiments, the inlet end wall 206 comprises a plurality of openings 208 extending through the inlet end wall 206. Stated differently, the inner channel 210 has an inlet end 204 having an inlet end wall 206 with a plurality of openings 208 extending therethrough.

The inner channel 210 extends from the inner channel face of the inlet end wall 206 to the outlet end 205 with an opening 212 in the outlet end face 209. The inner channel 210 is bounded by the channel wall 211.

In the illustrated embodiments, the inner channel 210 comprises an upper portion 214 and a lower portion 216. The upper portion 214 extends an upper portion length from the inlet end wall 206 to the lower portion 216. The upper portion 214 of some embodiments has a substantially uniform inner diameter along the upper portion 214 length. The lower portion 216 of the inner channel 210 has a flared profile, as shown in the Figures, with an increasing diameter from the upper portion 214 to the outlet end face 209. The transition from the upper portion 214 to the lower portion 216 occurs at the point where the channel wall 211 of the inner channel 210 changes from a uniform inner diameter to an increasing inner diameter. The upper portion 214 and lower portion 216 align with the upper portion 202 and lower portion 203 of the gas insert 200.

Referring to FIGS. 2 and 3, in some embodiments, the outer peripheral surface 207 of the gas insert 200 includes one or more peripheral channel 250 formed therein. The one or more peripheral channel 250 is a recessed portion of the outer peripheral surface 207 configured to hold an O-ring 251. In the embodiment shown, there are four peripheral channels 250 spaced above and below each of the inlet end gas injection level 220, the intermediate gas injection level 230 and the outlet end gas injection level 240. The one or more peripheral channel 250 have O-rings 251 that aid in the formation of a fluid-tight seal between the various gas injection levels to minimize or eliminate leakage.

In some embodiments, as shown in FIGS. 2-4, the inlet end 204 of the gas insert 200 comprises a flange 218 extending outwardly from the outer peripheral surface 207 of the gas insert 200. In the embodiment illustrated, the flange 218 is part of the inlet end wall 206.

In use, the outlet end face 209 of the outlet end 205 of the gas insert 200 is in contact with the back surface 122 of the backing plate 120. The gas insert 200 can be connected to the backing plate 120 by any suitable fastener or connection type known to the skilled artisan.

Operation of the gas insert 200 in use is described with respect to the three gas injection level embodiment shown in the Figures. The skilled artisan will understand the operation of the system using a gas insert 200 with a different number of injection levels. A first gas is flowed through inlet line 229 in fluid communication with the inlet end gas injection level 220 through the gas manifold 195. A second gas is flowed through inlet line 239 in fluid communication with the intermediate gas injection level 230 through the gas manifold 195. The second gas and the first gas can be the same or different. A third gas is flowed through the inlet line 249 in fluid communication with the outlet end gas injection level 240 through the gas manifold 195. The third gas can be the same as one or more of the first gas or second gas, or different from both the first gas and second gas. In some embodiments, the third gas is an inert or diluent gas.

Some embodiments of the semiconductor manufacturing processing chamber 100 further comprise a remote plasma source (RPS) 185 connected to the gas manifold 195. In use, a plasma generated in the remote plasma source 185 flows through the plurality of openings 208 in the inlet end wall 206 of the gas insert 200 into the inner channel 210 and the gas box plenum 129. In some embodiments, an inert gas purge line (not shown) is connected to the inner channel 210 of the gas insert 200 (i.e., between the inlet end wall 206 and the inlet end gas injection level 220) to provide a continuous inert gas purge to prevent back streaming of gases to the remote plasma source 185. In some embodiments, inclusion of the inert gas purge eliminates the need for an isolation valve through continuous inert gas purge.

In some embodiments that use a remote plasma source (RPS) 185, a gas is flowed from the remote plasma source 185 through the plurality of openings plurality of openings 208 into the inner channel 210, a first gas is flowed into the inlet end gas injection level 220, a second gas is flowed into the intermediate gas injection level 230 have the same composition, and a third gas is flowed into the outlet end gas injection level 240, where the reverse flow from the outlet end gas injection level 240 creates turbulence and mixes the gases together. In this configuration, the first gas and second gas (and possibly third gas) can be the same species or different species which may react with the gas from the remote plasma source 185 (if a reactive gas is flowed). The skilled artisan will recognize the various reactive and non-reactive gas flow streams possible with the various embodiments.

Referring again to FIG. 1, the semiconductor manufacturing processing chamber 100 comprises a substrate support 170 within the chamber interior 105. The substrate support 170 of some embodiments comprises a support body 171 positioned on a support shaft 172. The support body 171 has a support surface 173 configured to support a semiconductor wafer 108 for processing. The support shaft 172 of some embodiments is configured to move the support body 171 closer to/further from the faceplate 130 and/or around a rotational axis 175 of the support shaft 172. During processing, the support surface 173 is spaced from the front surface 131 of the faceplate 130 to form a process gap 109.

In some embodiments, the support body 171 includes a thermal element 174 configured to heat the semiconductor wafer 108 on the support surface 173. The thermal element 174 can be any suitable heating mechanism known to the skilled artisan. For example, in some embodiments, the thermal element 174 comprises a resistive heating element that is connected to a power supply (not shown) configured to apply power to the thermal element 174 to heat the support body 171. In some embodiments, the support body 171 includes an electrostatic chuck (ESC) (not shown). The skilled artisan will be familiar with the construction of the ESC and the manner in which the ESC is powered and employed.

In some embodiments, as shown in FIG. 1, the semiconductor manufacturing processing chamber 100 includes a radio-frequency (RF) shield 150. The RF shield 150 is a generally ring-shaped component that is positioned within the interior 105 of the semiconductor manufacturing processing chamber 100 between the substrate support 170 and the sidewall 102. The RF shield 150 surrounds the support surface 173 of the substrate support 170 and helps to prevent reactive gases from flowing from the process gap 109 to the interior 105 of the chamber body 101.

The RF shield 150 has a top end and a bottom end. The top end of some embodiments has a sloped surface configured to direct a gas flow toward the pumping ring 140. In some embodiments, the top end of the RF shield 150 has a top end surface that is coplanar with the support surface 173 of the substrate support 170. In some embodiments, where the top end surface of the RF shield 150 is sloped, as shown in the Figures, the highest point of the top end surface is coplanar with the support surface 173 of the substrate support 170. In some embodiments, the top end of the RF shield 150 has a top end surface that is below the level of the support surface 173.

A pumping ring 140 is positioned on a top surface of the choke plate 160. The pumping ring 140 has a front surface and a back surface defining a thickness of the pumping ring 140. In use, the back surface of the pumping ring 140 is positioned adjacent to or in contact with the front surface 131 of the faceplate 130. In some embodiments, in use, the front surface of the pumping ring 140 is positioned in contact with the top surface of the choke plate 160.

The pumping ring 140 of some embodiments comprises a vacuum plenum configured to remove process gases from an interior of the processing chamber. The vacuum plenum is formed by the recess in the front surface of the pumping ring 140 when the front surface of the pumping ring 140 is adjacent another surface. For example, as shown in FIG. 1, when the pumping ring 140 is positioned so that the front surface is adjacent to or in contact with the choke plate 160 or chamber sidewall 102, a pumping volume 145 is formed.

In some embodiments, the pumping ring 140 is connected to the backing plate 120 with a plurality of fasteners (not shown) that extend through the faceplate 130. In some embodiments, bolting the backing plate 120 to the pumping ring 140 sandwiches the faceplate 130 between the backing plate 120 and the pumping ring 140.

In some embodiments, at least one aperture 146 extends between the recess 143 in the front surface of the pumping ring 140 and the back surface 142 of the pumping ring 140. In some embodiments, the at least one aperture 146 extends between the recess 143 in the front surface of the pumping ring 140 and an inner face of the pumping ring 140. The at least one aperture 146 has a radius equal to a radius of the front surface opening of the angled openings in the faceplate 130.

During use, the backing plate 120, faceplate 130 and pumping ring 140, in addition to other components, may be separated by one or more O-rings to help maintain a fluid-tight seal for the processing chamber. In some embodiments, the gas distribution assembly 110 includes a plurality of O-rings positioned between the backing plate 120 and the faceplate 130 and/or a plurality of O-rings positioned between the faceplate 130 and the pumping ring 140. In some embodiments, the pumping ring 140 is connected to the choke plate 160 with at least one O-ring positioned between.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A gas insert for a semiconductor manufacturing processing chamber, the gas insert comprising:
a plurality of gas injection levels, each gas injection level providing a gas flow to an inner channel within the gas insert, each of the gas flows directed in a rotational direction within the inner channel, the gas injection level closest to an outlet end of the gas insert directs a gas flow in an opposite rotational direction than the other gas injection levels.

2. The gas insert of claim 1, wherein the plurality of gas injection levels comprising an inlet end gas injection level closest to the inlet end, and the gas injection level closest to the outlet end.

3. The gas insert of claim 1, wherein there are three gas injection levels: an inlet end gas injection level closest to the inlet end of the gas insert, an intermediate gas injection level, and an outlet end gas injection level, the outlet end gas injection level furthest from the inlet end of the gas insert.

4. The gas insert of claim 3, wherein each gas injection level comprises a peripheral recesses in an outer peripheral wall of the gas insert and a plurality of angled apertures extending from a bottom surface of the peripheral recess to the inner channel.

5. The gas insert of claim 4, wherein the inlet end gas injection level comprises in the range of 4 to 10 angled apertures spaced around the bottom surface of the peripheral recess.

6. The gas insert of claim 4, wherein the intermediate gas injection level comprises in the range of 4 to 10 angled apertures spaced around the bottom surface of the peripheral recess.

7. The gas insert of claim 4, wherein the outlet end gas injection level comprises in the range of 6 to 24 angled apertures spaced around the bottom surface of the peripheral recess.

8. The gas insert of claim 4, wherein the plurality of angled apertures in one or more of the inlet end gas injection level, intermediate gas injection level or outlet end gas injection level are angled tangential to the inner channel.

9. A gas insert for a semiconductor manufacturing processing chamber, the gas insert comprising:
an inlet end having an inlet end wall with a plurality of openings extending therethrough;
an outlet end having an outlet end face, the inlet end and outlet end defining a length of the gas insert;
an inner channel extending from the inlet end wall to the outlet end with an opening in the outlet end face, the inner channel bounded by a channel wall;
a plurality of gas injection levels, each gas injection level comprising a peripheral recess in an outer peripheral wall of the gas insert, the plurality of gas injection levels comprising an inlet end gas injection level and an outlet end gas injection level, each of the peripheral recesses having a plurality of angled apertures extending from a bottom surface of the peripheral recess to the inner channel.

10. The gas insert of claim 9, wherein the inner channel comprises an upper portion and a lower portion, the upper portion extending an upper portion length from the inlet end wall, the upper portion having a substantially uniform diameter along the upper portion length, the lower portion having a flared profile with an increasing diameter from the upper portion to the outlet end face.

11. The gas insert of claim 10, wherein the plurality of angled apertures in each of the gas injection levels connects to the inner channel in the upper portion.

12. The gas insert of claim 9, wherein there are three gas injection levels: an inlet end gas injection level closest to the inlet end of the gas insert, an intermediate gas injection level, and an outlet end gas injection level, the outlet end gas injection level furthest from the inlet end of the gas insert.

13. The gas insert of claim 12, wherein each of the inlet end gas injection level and intermediate gas injection level independently comprise in the range of 4 to 10 angled apertures spaced around the bottom surface of the peripheral recess.

14. The gas insert of claim 12, wherein the outlet end gas injection level comprises in the range of 6 to 24 angled apertures spaced around the bottom surface of the peripheral recess.

15. The gas insert of claim 14, wherein the outlet end gas injection level comprises at least 2× the number of angled apertures than either the inlet end gas injection level or intermediate gas injection level.

16. The gas insert of claim 12, wherein the plurality of angled apertures in one or more of the inlet end gas injection level, intermediate gas injection level or outlet end gas injection level are angled tangential to the inner channel.

17. The gas insert of claim 12, wherein the plurality of angled apertures in one or more of the inlet end gas injection level, intermediate gas injection level or outlet end gas injection level are angled toward the outlet end of the gas insert and connect to the inner channel tangential to the channel wall.

18. The gas insert of claim 9, wherein the inlet end of the gas insert comprises a flange extending outwardly from an outer surface of the gas insert.

19. A gas injector assembly for a semiconductor manufacturing processing chamber comprising:
a showerhead having a front surface and a back surface with a plurality of apertures extending therethrough;
a backing plate having a front surface with a concave portion and a back surface with an opening extending to the concave portion of the front surface, the backing plate positioned adjacent the back surface of the showerhead to form a plenum between the concave portion of the front surface and the back surface of the showerhead;
a gas insert having an outlet end in contact with the back surface of the backing plate, the gas insert comprising a plurality of gas injection levels, each gas injection level providing a gas flow to an inner channel within the gas insert, each of the gas flows directed in a rotational direction within the inner channel, the gas injection level closest to an outlet end of the gas insert directs a gas flow in an opposite rotational direction than the other gas injection levels, the inner channel in fluid communication with the plenum through the back surface of the backing plate; and
a gas manifold around the gas insert, the gas manifold cooperatively interacting with the gas insert to form peripheral recesses for the gas injection levels.

20. The processing chamber of claim 19, wherein each gas injection level of the gas insert comprises a peripheral recesses in an outer peripheral wall of the gas insert and a plurality of angled apertures extending from a bottom surface of the peripheral recess to the inner channel, the plurality of angled apertures in one or more of the inlet end gas injection level, intermediate gas injection level or outlet end gas injection level are angled tangential to the inner channel.
